(19) United States
(12) Patent Application Publication
(10) Pub. No.: US 2024/0363376 A1
(43) Pub. Date: Oct. 31, 2024

(54) INFRARED REFLOW DEVICE

(71) Applicant: National Pingtung University of Science and Technology, Pingtung County (TW)

(72) Inventor: Wei-Hua Lu, Pingtung County (TW)

(21) Appl. No.: 18/380,255

(22) Filed: Oct. 16, 2023

(30) Foreign Application Priority Data
Apr. 25, 2023 (TW) 112115422

(51) Int. Cl. H01L 21/67; H01L 21/60

(52) U.S. Cl. CPC H01L 21/67115; H01L 21/60; H01L 21/67103; H01L 2021/60105; H01L 2021/6015

(57) ABSTRACT

An infrared reflow device includes an infrared heater and a heat conductor. Infrared radiation sources on the infrared heater are provided to emit a first infrared radiation of a first wavelength toward a semiconductor device. The heat conductor is placed between the infrared heater and the semiconductor device to absorb the first infrared radiation and radiate a second infrared radiation of a second wavelength toward the semiconductor device to reflow the semiconductor device. The second infrared radiation can be absorbed in a substrate of the semiconductor more efficiently than the first infrared radiation.

### FIELD OF THE INVENTION

This invention relates to an infrared reflow device, and more particularly to an infrared reflow device with heat conductor.

### BACKGROUND OF THE INVENTION

In conventional reflow treatment, a semiconductor device is heated by a reflow device to melt connectors on the semiconductor device and connect the semiconductor device to another electronic component. Infrared reflow device is generally used in reflow process because it has advantages of wide heating range and better heating efficiency. An infrared thermal source is usually provided in infrared reflow device to emit infrared radiation toward the semiconductor device such that the semiconductor device is warmed up to heat the connectors. However, reflow device using shortwave infrared is not suitable for all kind of semiconductor devices. For instance, reflow device using shortwave infrared is not suitable for a semiconductor device with glass substrate in reflow treatment due to absorption efficiency of shortwave infrared is extremely weak in glass. Thus, it can be seen that application of infrared reflow device is restricted by weak infrared absorption in some materials.

### SUMMARY

One object of the present invention is to heat a heat conductor by a first infrared radiation generated by an infrared heater and radiate a second infrared radiation from the heat conductor to reflow a semiconductor device, thus an infrared reflow device of the present invention is applicable to different semiconductor devices in reflow treatment.

An infrared reflow device of the present invention includes an infrared heater and a heat conductor. The infrared heater includes infrared radiation sources which each is provided to emit a first infrared radiation of a first wavelength toward a semiconductor device. The heat conductor is placed between the infrared heater and the semiconductor device to absorb the first infrared radiation, and it is provided to radiate a second infrared radiation of a second wavelength toward the semiconductor device to reflow the semiconductor device. The second infrared radiation is absorbed more efficiently than the first infrared radiation by a substrate of the semiconductor device.

In the present invention, the heat conductor is provided between the infrared radiation sources and the semiconductor device to absorb the first infrared radiation from the infrared radiation sources and radiate the second infrared radiation toward the semiconductor device. Since the second infrared radiation is absorbed more efficiently than the first infrared radiation by the substrate of the semiconductor device, the semiconductor device can be heated and reflowed by absorption of the second infrared radiation.

### DESCRIPTION OF THE DRAWINGS

FIG. 1 is a cross-section view diagram illustrating an infrared reflow device in accordance with one embodiment of the present invention.

FIG. 2a is a top view diagram illustrating a heat conductor of an infrared reflow device in accordance with a first embodiment of the present invention.

FIG. 2b is a cross-section view diagram illustrating the heat conductor of the infrared reflow device in accordance with the first embodiment of the present invention.

FIG. 3a is a top view diagram illustrating a heat conductor of an infrared reflow device in accordance with a second embodiment of the present invention.

FIG. 3b is a cross-section view diagram illustrating the heat conductor of the infrared reflow device in accordance with the second embodiment of the present invention.

### DETAILED DESCRIPTION OF THE INVENTION

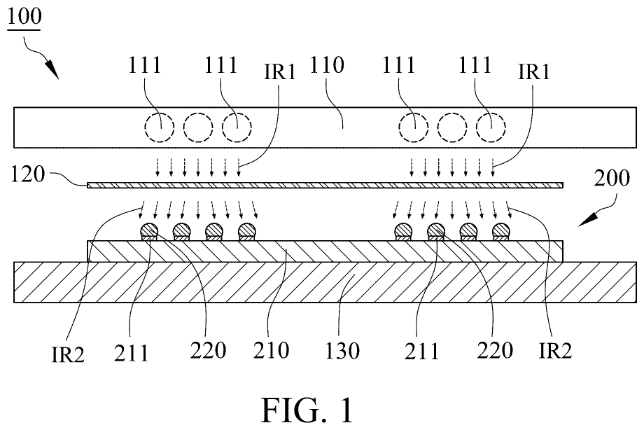

FIG. 1 is a cross-section view diagram illustrating an infrared reflow device 100 in accordance with an embodiment of the present invention. The infrared reflow device 100 includes an infrared heater 110 and a heat conductor 120. The infrared heater 110 involves multiple infrared radiation sources 111 which each is provided to emit a first infrared radiation IR1 of a first wavelength toward a semiconductor device 200. In the embodiment, the first infrared radiation IR1 is a continuous-wave infrared radiation having a peak wavelength between 780 nm and 1400 nm.

The semiconductor device 200 is placed on a holder 130 and includes a substrate 210 and multiple conductive elements 220. Each of the conductive elements 220 is connected to one of conductive pads 211 arranged on the substrate 210. The substrate 210 can be connected to other electronic components via the conductive elements 220 which may be solder balls or solder bumps. Conventional semiconductor device generally includes a silicon substrate which can absorb the first infrared radiation IR1 with the first wavelength from the infrared radiation sources 111. If the substrate 210 of the semiconductor device 200 is not a silicon substrate, for example, the substrate 210 is a glass substrate, absorption efficiency of the first infrared radiation IR1 by the substrate 210 is too weak and insufficient to heat and reflow the substrate 210.

With reference to FIG. 1, the heat conductor 120 is placed between the infrared heater 110 and the semiconductor device 200, thus the heat conductor 120 can be heated by absorption of the first infrared radiation IR1 and then radiate a second infrared radiation IR2 of a second wavelength toward the semiconductor device 200. In the embodiment, the second infrared radiation IR2 is a continuous-wave infrared radiation having a peak wavelength between 1400 nm and 4000 nm, and it can be absorbed by a non-silicon substrate. Owing to the second infrared radiation IR2 can be absorbed in the substrate 210 more efficiently than the first infrared radiation IR1, and heat can be convected away from the heat conductor 120 to the semiconductor device 200, the second infrared radiation IR2 from the heat conductor 120 is sufficient to reflow the semiconductor device 200. Thus, the infrared heater 110 of the present invention is suitable for different semiconductor devices.

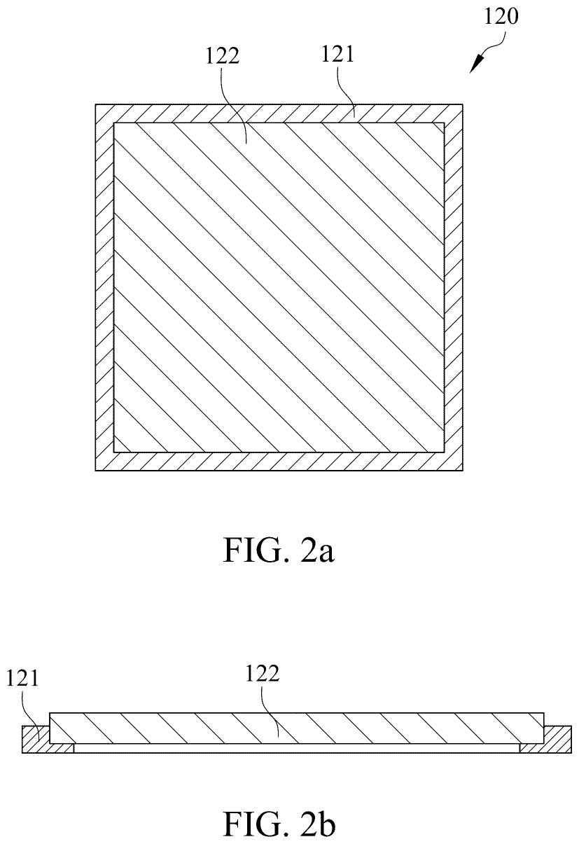

The heat conductor 120 of a first embodiment of the present invention is shown in FIGS. 2a and 2b, and it includes a carrier 121 and a heat conductive plate 122. The heat conductive plate 122 is mounted on the carrier 121 so as to be moved with the carrier 121, and it is made of silicon, e.g. single crystalline silicon, polycrystalline silicon or amorphous silicon. The heat conductive plate 122 can be heated by absorption of the first infrared radiation IR1 and radiate the second infrared radiation IR2. In the first embodiment, the heat conductive plate 122 carried by the carrier 121 can be placed as close as possible to the semiconductor device 200 to enhance heating efficiency of reflow treatment. Besides, the heat conductive plate 122 mounted on the carrier 121 can be replaced rapidly and easily while the heat conductive plate 122 is required to be replaced by another heat conductive plate.

Heating rate and durability of the heat conductive plate 122 depends on a thickness of the heat conductive plate 122, preferably, the heat conductive plate 122 having a thickness between 0.05 mm and 2 mm can provide the best balance between heating rate and durability.

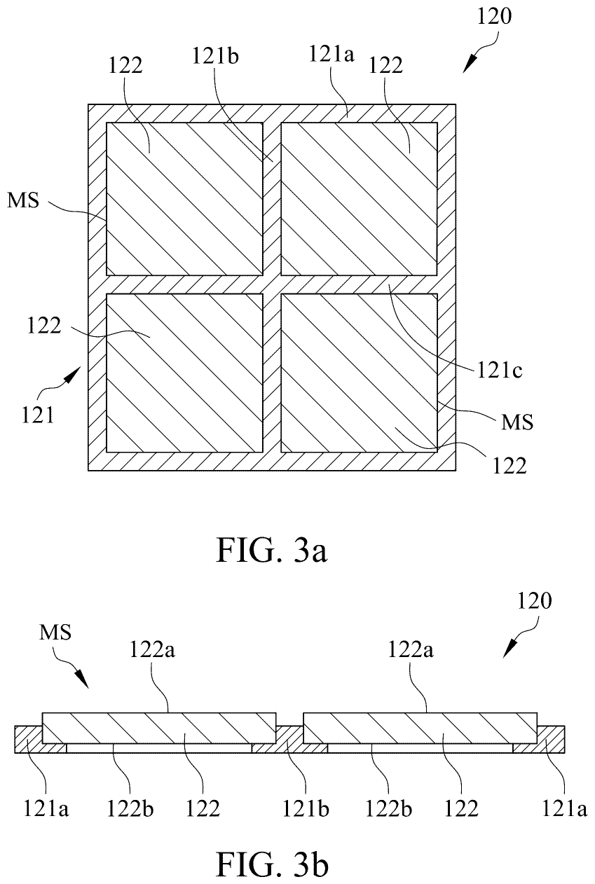

FIGS. 3a and 3b are provided to show the heat conductor 120 of a second embodiment of the present invention. Different to the first embodiment, the carrier 121 includes an outer frame 121a, a vertical rod 121b and a horizontal rod 121c, and the heat conductor 120 includes multiple heat conductive plates 122 in the second embodiment. Multiple mounting spaces MS are defined on the carrier 121 according to the outer frame 121a, the vertical rod 121b and the horizontal rod 121c, and each of the heat conductive plates 122 is mounted in one of the mounting spaces MS. A top surface 122a and a bottom surface 122b of each of the heat conductive plates 122 are visible from the carrier 121, the top surface 122a faces toward the infrared heater 110, and the bottom surface 122b faces toward the semiconductor device 200. The mounting spaces MS are divided by the vertical rod 121b and the horizontal rod 121c and are provided to accommodate the heat conductive plates 122. In the second embodiment, each of the heat conductive plates 122 is not only capable of absorbing the first infrared radiation IR1 and radiating the second infrared radiation IR2, but is also able to be aligned with position required for reflow treatment on the semiconductor device 200 by arrangement of the mounting spaces MS. Consequently, differential heating of the semiconductor device 200 is feasible, and position not required for reflow treatment is protected from heat damage during reflow process. Moreover, each of the heat conductive plates 122 of the second embodiment is smaller than that of the first embodiment, so manufacturing cost of the heat conductor 120 can be reduced in the second embodiment.

In the present invention, the heat conductor 120 is mounted between the infrared radiation sources 111 and the semiconductor device 200 to allow the heat conductor 120 to absorb the first infrared radiation IR1 from the infrared radiation sources 111 and radiate the second infrared radiation IR2 toward the semiconductor device 200. Since the second infrared radiation IR2 is absorbed by the substrate 210 of the semiconductor device 200 more efficiently than the first infrared radiation IR1, the semiconductor device 200 can absorb the second infrared radiation IR2 to be heated sufficiently during reflowing.

While this invention has been particularly illustrated and described in detail with respect to the preferred embodiments thereof, it will be clearly understood by those skilled in the art that is not limited to the specific features shown and described and various modified and changed in form and details may be made without departing from the scope of the claims.

What is claimed is:

1. An infrared reflow device comprising:
an infrared heater including a plurality of infrared radiation sources, each of the plurality of infrared radiation sources is configured to emit a first infrared radiation of a first wavelength toward a semiconductor device which includes a substrate; and
a heat conductor provided between the infrared heater and the semiconductor device, the heat conductor is configured to absorb the first infrared radiation and radiate a second infrared radiation of a second wavelength toward the semiconductor device to reflow the semiconductor device, wherein the second infrared radiation is configured to be absorbed by the substrate more efficiently than the first infrared radiation.

2. The infrared reflow device in accordance with claim 1, wherein the heat conductor includes a carrier and a heat conductive plate, and the heat conductive plate is mounted on the carrier.

3. The infrared reflow device in accordance with claim 2, wherein the heat conductive plate is made of silicon and has a thickness between 0.05 mm and 2 mm.

4. The infrared reflow device in accordance with claim 3, wherein a peak wavelength of the first infrared radiation is between 780 nm and 1400 nm, and a peak wavelength of the second infrared radiation is between 1400 nm and 4000 nm.

5. The infrared reflow device in accordance with claim 4, wherein the substrate of the semiconductor device is a glass substrate.

6. The infrared reflow device in accordance with claim 5, wherein the semiconductor device further includes a plurality of conductive elements, each of the plurality of conductive elements is configured to be connected to one of a plurality of conductive pads of the substrate.

7. The infrared reflow device in accordance with claim 2, wherein the heat conductive plate is made of single crystalline silicon, polycrystalline silicon or amorphous silicon.

8. The infrared reflow device in accordance with claim 2, wherein the carrier of the heat conductor includes an outer frame, a vertical rod and a horizontal rod, a plurality of mounting spaces are defined on the carrier according to the outer frame, the vertical rod and the horizontal rod, the heat conductor includes a plurality of heat conductive plates, each of the plurality of heat conductive plates is mounted in one of the plurality of mounting spaces, a top surface and a bottom surface of each of the plurality of heat conductive plates are visible from the carrier, the top surface is configured to face toward the infrared heater, and the bottom surface is configured to face toward the semiconductor device.

9. The infrared reflow device in accordance with claim 8, wherein each of the plurality of heat conductive plates is made of silicon and has a thickness between 0.05 mm and 2 mm.

10. The infrared reflow device in accordance with claim 9, wherein a peak wavelength of the first infrared radiation is between 780 nm and 1400 nm, and a peak wavelength of the second infrared radiation is between 1400 nm and 4000 nm.

11. The infrared reflow device in accordance with claim 10, wherein the substrate of the semiconductor device is a glass substrate.

12. The infrared reflow device in accordance with claim 11, wherein the semiconductor device further includes a plurality of conductive elements, each of the plurality of conductive elements is configured to be connected to one of a plurality of conductive pads of the substrate.

13. The infrared reflow device in accordance with claim 8, wherein each of the plurality of heat conductive plates is made of single crystalline silicon, polycrystalline silicon or amorphous silicon.
